(19) United States
(12) Patent Application Publication
(10) Pub. No.: US 2020/0245513 A1
(43) Pub. Date: Jul. 30, 2020

(54) COMPUTER SYSTEM

(71) Applicant: Fujitsu Client Computing Limited, Kawasaki (JP)

(72) Inventor: Wilhelm Neukam, Munchen (DE)

(21) Appl. No.: 16/748,853

(22) Filed: Jan. 22, 2020

(30) Foreign Application Priority Data
Jan. 30, 2019 (DE) 10 2019 102 347.5

(51) Int. Cl. H05K 9/00; H05K 5/02; H05K 7/14

(52) U.S. Cl. CPC H05K 9/0015; H05K 7/1424; H05K 5/0247; H05K 9/006

(57) ABSTRACT

A computer system includes a shielding casing, a movable component, at least one cable, and a shielding apparatus arranged at a first part of the shielding casing configured to accommodate the at least one cable in a first state at least partially, and to be compressed during a movement of the movable component in a second state, whereby the at least one cable is clamped into the shielding apparatus.

### TECHNICAL FIELD

This disclosure relates to a computer system comprising a shielding casing and at least one cable.

### BACKGROUND

Computer systems have to be compliant with predetermined specifications for electromagnetic compatibility (EMV). Hereto, shielding cases are used to prevent discharge of electromagnetic radiation generated by the computer system to the environment. However, in such computer systems there are numerous weak points that may impair electromagnetic shielding. As a result, the specifications of the EMV may not be fulfilled. In addition, electromagnetic radiation generated in the shielding casing may be received by components that may cause an impairment of the functionality of the components of the computer system.

JP 2000-77881 A discloses a computer system having a shielding casing and a shielding apparatus for cables arranged inside the casing. The shielding apparatus comprises a conductive enclosure that may accommodate signal cables and may be closed by a conductive fastening means. However, it may be complicated and time-consuming to insert cables in such a shielding apparatus.

It could therefore be helpful to provide a computer system comprising an enhanced shielding concept.

### SUMMARY

I provide a computer system including a shielding casing, a movable component, at least one cable, and a shielding apparatus arranged at a first part of the shielding casing configured to accommodate the at least one cable in a first state at least partially, and to be compressed during a movement of the movable component in a second state, whereby the at least one cable is clamped into the shielding apparatus.

### BRIEF DESCRIPTION OF THE DRAWINGS

FIG. 1 is an interior view of a computer system according to an example.

FIG. 2 shows a gasket at the casing wall of the computer system according to an example in a first state.

FIG. 3 shows the gasket according to FIG. 2 in a second state.

FIG. 4 is a perspective view of a gasket for a computer system according to an example.

FIG. 5 is an interior view of a computer system according to a further example.

FIG. 6 is a perspective view of a tunnel-shaped shielding sheet for a computer system according to an example.

### LIST OF REFERENCE SIGNS

1 Computer system
2 Inner surface
3 Casing wall
4 Casing
5 Electric component
6 Hook
7 Cable
8 Gasket
9 First Leg
10 Second Leg
11 Drive cage
12 Drive cage side
13 Foam core
14 Electrically conductive fabric
15 Tunnel-shaped shielding sheet
16 Bulge
17 Free end
18 Slot
19 Fin
A First state
B Second state
X First region
Y Second Region

### DETAILED DESCRIPTION

My computer system may comprise a shielding casing, a movable component and at least one cable. Furthermore, the computer system may comprise a shielding apparatus arranged at a first part of the shielding casing configured to accommodate the at least one cable in a first state at least partially, and to be compressed during a movement of the movable component in a second state. Thus, the at least one cable is clamped into the shielding apparatus.

This way, the shielding apparatus prevents the cable from receiving or discharging electromagnetic radiation inadvertently. In addition, by the shielding apparatus, it is ensured that in an operating state, that is, when the shielding apparatus is compressed and the at least one cable is clamped into the shielding apparatus, the at least one cable is stored in a secure way.

The shielding apparatus may comprise or consist of an electrically conductive foam.

The electrically conductive foam may, for example, be a conventional foam, for example, polyethylene interwoven by electrically conductive materials. Alternatively, it may comprise a conventional foam provided with an electrically conductive layer. These types of electrically conductive foams are also known as gaskets.

An advantage of using an electrically conductive foam for the shielding apparatus is that tolerances in the computer system, in particular during compressing the shielding apparatus, are compensated for. Further, the electrically conductive foam reduces the risk of damaging the at least one cable, in particular during compression of the shielding apparatus.

The shielding apparatus may comprise a V- or U-shaped profile when viewed in a cross-section.

In this example, the cross-section plane in which the shielding application comprises a V- or U-shaped profile is a plane whose normal vectors extend parallel to a main extension direction of the at least one cable.

Advantageously, in such a shielding apparatus, the at least one cable is arranged in a deepest point of the V- or U-shaped profile of the shielding application in a secure and well protected way. In addition, this ensures an utmost extensive contact of the shielding apparatus with an outer surface of the at least one cable. This guarantees a high degree of shielding of the at least one cable against electromagnetic radiation.

Further advantages are disclosed in the following description of examples. The examples will be described by the following Figures.

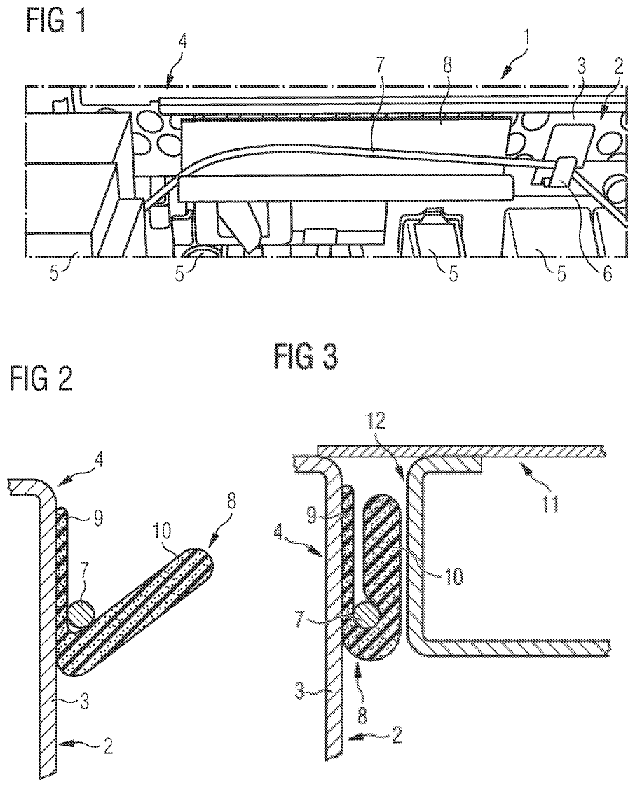

FIG. 1 shows an interior view of the computer system 1 when viewed towards an inner surface of a casing wall 3. The casing wall 3 is part of a shielding casing 4 of the computer system 1, that is the casing wall 3 is electrically conductive. The portion of the computer system 1 of FIG. 1 shows a variety of electrical components 5 of the computer system 1, wherein the description thereof is omitted here.

The casing wall 3 comprises annular ventilation holes, and a hook 6 directed towards an interior of casing 4. The hook 6 is bent from the casing wall 3 to the outside and configured to support a cable 7 which extends inside the casing 4.

In the example, the cable 7 is an antenna cable that connects a WLAN (Wireless Local Area Network) module, which is not shown here, to a WLAN antenna, which is not shown here. Such WLAN antenna projects to the outside of casing 4 from casing 4 and is configured to send or receive data via a WLAN. As the cable 7 is connected to the antenna projecting to the outside, the electromagnetic waves received in the interior of the casing 4 from the cable 7 may be discharged as interfering electromagnetic radiation via the antenna. Such kind of electromagnetic radiation, which is received by the cable 7 in the interior of casing 4, may be generated by other components in the interior of the computer system 1, for example.

At the inner surface 2 of the casing wall 3, a gasket 8 is fixed which is configured to receive the cable 7. In the core thereof, the gasket 8 consists of an electrically non-conductive foam enclosed by a conductive fabric and extending along the cable 7 at the casing wall 3. Alternatively, as gasket 8 a gasket made of an electrically conductive foam may be used. In the example shown here, the gasket 8 extends some centimeters along the casing wall 3. This corresponds to an appropriate length of the gasket 8 to receive a portion of the cable system as large as possible and at the same time to not interfere with any further components in the casing 4 at the casing wall 3. The gasket 8 comprises a V-shaped profile as seen in the cross-section, and will be described in more detail referring to FIGS. 2 to 4.

The gasket 8 prevents or reduces reception of electromagnetic interference radiation by the cable 7 inside the casing 4. Thus, a discharge of interfering radiation via the antenna is prevented or at least reduced. As the gasket 8 is directly fixed to the electrically conductive casing wall 3, the electromagnetic waves received from the gasket 8 may be discharged to the casing 4. The casing 4 is connected to ground, thus no or neglectable interference radiation may be discharged by casing 4, and the computer system 1 provides an enhanced shielding concept regarding compatibility.

In the example shown here, the gasket 8 is fixed to the electrically conductive casing wall 3. Alternatively, the gasket 8 may also be fixed to an electrically conductive chassis or any other suitable electric conductive component of the computer system 1.

FIGS. 2 and 3 show a part of a casing wall 3 of the casing 4 of a computer system 1 including a gasket 8 and a cable 7 received in the gasket 8 as seen in a cross-section. In FIGS. 2 and 3, the cross-section plane is chosen in a way that a normal vector of the cross-section plane extends parallel to the main extending direction of the cable 7. The casing wall 3 and the gasket 8 including the cable 7 correspond to the casing wall 3 and the gasket 8 including the cable 7 according to FIG. 1, for example.

FIG. 2 shows the gasket 8 in a first state A. FIG. 3 shows the gasket 8 in a second state B. The first state A corresponds to a mounting state, that is, the state in which the gasket 8 is during mounting to the casing wall 3. The first state A is also shown in FIG. 1. In the first state, the gasket 8 having a V-shaped profile is bonded to the first leg 9 of the gasket 8 to the casing wall 3. Hereto, an electrically conductive adhesive is used. Thus, the gasket 8 is connected to casing wall 3 in an electrically conductive way. Alternatively, the gasket 8 may also be riveted, welded, screwed or fixed in any other way. A second leg 10 of the gasket 8 projects in an angle of about 45° from the first leg 9. By this V-shaped opening of the gasket, the cable 7 may be easily inserted into the gasket 8 in a first state A.

FIG. 3 shows the gasket 8 in the second state B. The second state B is an operating state in which the gasket 8 is during operation of the computer system 1. In the second state B, the second leg 10 of the gasket 8 is pressed towards the first leg 9 of the gasket 8 by a part of a drive cage 11. The first leg 9 and the second leg 10 are basically parallel to each other.

A transition from the first state A to the second state B is achieved by inserting the drive cage 11 into the casing 4. When, during mounting of the drive cage 11, the drive cage 11 is moved towards the casing wall 3, the surface 12 of the drive cage 11 presses the second leg 10 of the gasket 8 towards the first leg 9. In a second state B, the cable 7 is clamped into the gasket 8. Thus, it is not arranged freely in the casing 4. In the second state B, the perimeter of the shell of the cable 7 is in contact with the inner surface of the gasket 8 to a degree of more than 50%.

In the example shown here, the surface 12 of the drive cage 11 presses the gasket 8 in a second state. Thus, the cable 7 is clamped into the gasket 8 as soon as the drive cage 11 is inserted into the casing 4. Thus, the cable is accommodated in a safe way, for example, during maintenance work at the computer system 1 which does not require any removing of the drive cage 11, or the cable 7 may not be damaged by such maintenance work inadvertently.

In the illustration shown in FIG. 3, a first leg 9 and a second leg 10 do not contact each other. However, alternatively, it may be possible that in the second state B the gasket 8 is compressed to such a degree that the first leg 9 and the second leg 10 contact each other in the second state B.

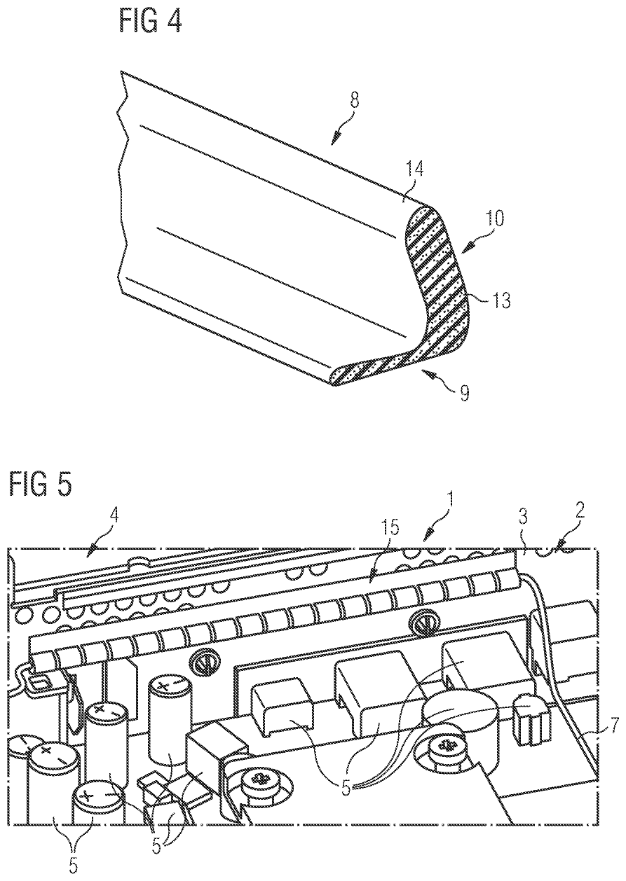

FIG. 4 shows a perspective illustration of gasket 8 as used in the previous Figures, for example. The gasket 8 according to FIG. 4 is shown in the first state A which is shown in FIGS. 1 and 2. The first leg 9 and the second leg 10 of the gasket 8 project from another in an angle of about 45°.

The gasket 8 includes a foam core 13 at the second leg 10 enclosed by an electrically conductive fabric 14. The gasket 8 is configured in a way that the foam core 13 is mainly supported in the second leg 10. The first leg 9 with which the gasket 8 may be fixed to a casing wall is nearly exclusively formed by the electrically conductive fabric 14.

This way, a gasket 8 is generated as narrow as possible, wherein a cable received in the gasket 8 is also sufficiently protected against pressure by the foam core 13 generated by compressing the gasket 8. The electrically conductive fabric 14 shields the cable 7 against electromagnetic radiation.

FIG. 5 shows an interior view of the computer system 1 as viewed towards an interface 2 of a casing wall 3 according to a further example. As shown in FIG. 1, the casing wall 3 is here also part of a shielding casing 4 of the computer system 1, that is, the casing wall 3 is electrically conductive. The section of the computer system 1 shown in FIG. 5 shows a variety of electrical components 5 of the computer system 1, the description thereof is omitted here.

Inside the casing 4 a cable 7 extends. In the example, as in the examples according to FIG. 1, the cable 7 is an antenna cable that connects the WLAN module, which is not shown here, to a WLAN antenna, which is not shown here.

At the inner surface 2 of the casing wall 3 a tunnel-shaped shielding sheet 15 is fixed and configured to receive the cable 7. The tunnel-shaped shielding sheet 15 is formed of an electrically conductive spring sheet-metal extending along the main extending direction of the cable 7 at the housing wall 3 in a tunnel shape. Alternatively, the shielding sheet 15 may also be made from a copper beryllium sheet or another suitable electrically conductive sheet-metal or comprise such.

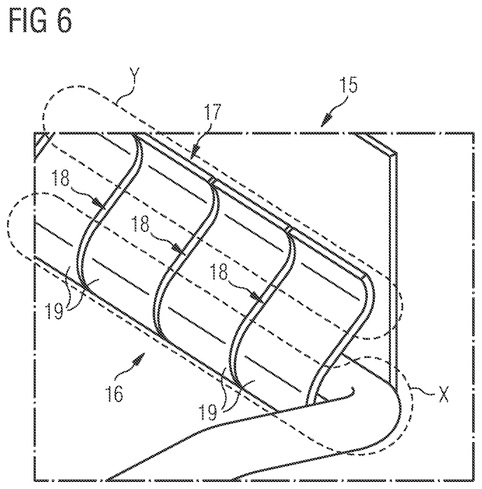

In the example shown here, the shielding sheet 15 extends some centimeters along the casing wall 3. This equals an appropriate length of the shielding sheet 15 to receive a portion of the cable 7 as large as possible and also to not interfere with further components in the casing 4 or at the casing wall 3. The shielding sheet 15 will be described in detail referring to FIG. 6.

As in the gasket 8 according to FIG. 1, the shielding sheet 15 prevents or reduces reception of electromagnetic interference radiation by the cable 7 inside the casing 4. Thus, a discharge of interfering radiation via the antenna is prevented or at least reduced. As the shielding sheet 15 is directly fixed to the electrically conductive casing wall 3, electromagnetic waves received from the shielding sheet 15 may be discharged to the casing 4. The casing 4 is connected to ground. Thus, no or neglectable interference radiation may be discharged by the casing 4, and the computer system 1 provides an enhanced shielding concept regarding electromagnetic compatibility. The shielding sheet 15 is riveted, welded, screwed or bonded by an electrically conductive adhesive to the casing wall 3. Thus, a well conducting electrical contact is ensured between the shielding casing 4 and the shielding sheet 15.

In the example shown here, the gasket 15 is fixed to the electrically conductive casing wall 3. Alternatively, the shielding sheet 15 may also be fixed to an electrically conductive chassis or any other suitable electric conductive component of the computer system 1.

FIG. 6 shows a perspective illustration of a tunnel-shaped shielding sheet 15 as it is used in computer system 1 according to FIG. 5, for example.

The shielding sheet 15 comprises a plane first leg 9 and a second leg 10 that is bent in a S-shape when viewed in profile. At the first leg 9, the shielding sheet 15 may be fixed to a casing wall. The second leg 10 is bent in a S-shape such that in the first region X, at a deepest point of the shielding sheet 15, wherein the first leg 9 is connected to the second leg 10, a bulge 16 exists in which a cable 7 is accommodated. The S-shaped bending of the second leg 10 is further configured in a way that in a second region Y of a free end 17 of the second leg 10, the second leg 10 is positioned closer to the first leg 9 as at the position of bulge 16. This way, the cable 7 is safely accommodated in the shielding sheet 15 and protected against inadvertently releasing from the shielding sheet 15.

In the example shown here, the second leg 10 of the shielding sheet 15 is further segmented, that is, the second leg 10 of the shielding sheet 15 comprises a plurality of slits 18 perpendicular to the main extending direction of the cable 7. This way, the second leg 10 is formed by a plurality of single fins 19 each having a width of about 0.5 cm to 1 cm. Of course, fins having other widths are also possible. The segmentation facilitates an introduction of the cable 7 into the shielding sheet 15, as the cable 7 may be compressed during gradual insertion through one or some of the fins 19 into the bulge 16 without having to compress the cable 7 along a complete extension length of the tunnel-shaped shielding sheet 15 at one time.

1. A computer system comprising:
a shielding casing,
a movable component,
at least one cable, and
a shielding apparatus arranged at a first part of the shielding casing configured to accommodate the at least one cable in a first state at least partially, and to be compressed during a movement of the movable component in a second state, whereby the at least one cable is clamped into the shielding apparatus.

2. The computer system according to claim 1, wherein the shielding apparatus and the movable component are arranged in an interior space of the shielding casing in the second state, and the at least one cable extends at least partially in the interior space of the shielding casing.

3. The computer system according to claim 2, wherein the movable component is part of a drive cage.

4. The computer system according to claim 2, wherein the at least one cable extends at least partially outside of the shielding casing or is electrically connected to a component arranged outside of the shielding casing.

5. The computer system according to claim 4, wherein the at least one cable is at least one antenna cable connected to at least one antenna positioned outside of the shielding casing.

6. The computer system according to claim 1, wherein the shielding apparatus comprises or consists of an electrically conductive foam.

7. The computer system according to claim 1, wherein the shielding apparatus comprises a V-shaped or U-shaped profile when viewed in a cross-section.

8. The computer system according to claim 3, wherein the at least one cable extends at least partially outside of the shielding casing or is electrically connected to a component arranged outside of the shielding casing.

9. The computer system according to claim 2, wherein the shielding apparatus comprises or consists of an electrically conductive foam.

10. The computer system according to claim 3, wherein the shielding apparatus comprises or consists of an electrically conductive foam.

11. The computer system according to claim 4, wherein the shielding apparatus comprises or consists of an electrically conductive foam.

12. The computer system according to claim 5, wherein the shielding apparatus comprises or consists of an electrically conductive foam.

13. The computer system according to claim 2, wherein the shielding apparatus comprises a V-shaped or U-shaped profile when viewed in a cross-section.

14. The computer system according to claim 3, wherein the shielding apparatus comprises a V-shaped or U-shaped profile when viewed in a cross-section.

15. The computer system according to claim 4, wherein the shielding apparatus comprises a V-shaped or U-shaped profile when viewed in a cross-section.

16. The computer system according to claim 5, wherein the shielding apparatus comprises a V-shaped or U-shaped profile when viewed in a cross-section.

17. The computer system according to claim 6, wherein the shielding apparatus comprises a V-shaped or U-shaped profile when viewed in a cross-section.
